(19) United States
(12) Patent Application Publication
(10) Pub. No.: US 2005/0121143 A1
(43) Pub. Date: Jun. 9, 2005

(54) Pump baffle and screen to improve etch uniformity

(75) Inventors: John Daugherty, Newark, CA (US); Neil Benjamin, E. Palo Alto, CA (US); Song Huang, Fremont, CA (US)

Correspondence Address: IPSG, P.C., P.O. BOX 700640, SAN JOSE, CA, 95170-0640, US

(73) Assignee: Lam Research Corporation, Fremont, CA (US)

(21) Appl. No.: 10/966,750

(22) Filed: Oct. 15, 2004

Related U.S. Application Data
(63) Continuation of application No. 10/155,061, filed on May 25, 2002, now Pat. No. 6,821,378.

(51) Int. Cl. H01L 21/306; C23F 1/00

(52) U.S. Cl. 156/345.29

(57) ABSTRACT

A cylindrical pump baffle fitted to a semiconductor processing chamber is disclosed. The pump baffle contains a screen with bores therethrough to allow process gasses from the process chamber to be exhausted from the chamber at a reduced rate. This decreases process discrepancies to the wafer due to the prejudice of gas concentration as a result of the pressure differential imposed upon the gas and thereby the wafer brought about by the rapid and relatively unimpeded exit flow of process gasses when no restrictive member is in place. The pump baffle is also machined such that it does not block the placement and removal of wafers by the platform robot arm.

### CROSS REFERENCE TO RELATED APPLICATIONS

This application claims priority from prior U.S. Provisional Patent Application No. 60/293,804 filed May 25, 2001 and entitled “Pump Baffle and Screen to Improve Etch Uniformity.”

### BACKGROUND OF THE INVENTION

1. Field of the Invention

The present invention relates to semiconductor processing equipment, and more particularly, to a pump baffle and screen used to improve etch uniformity for processes utilized on that equipment.

2. Description of the Related Art

Two of the most common types of semiconductor processes are plasma etch and deposition. These processes are accomplished via the use of a sealed chamber wherein the silicon wafer or workpiece is transported into the chamber and is exposed to a variety of process gasses to perform various types of operations upon the workpiece. The process gasses are removed from the chamber via a pump. Many of the pumps in plasma etch and deposition chambers are asymmetrically located. That is, the location of the pump is such that gas exits the chamber on one side of the wafer or workpiece as opposed to symmetrically on all sides of the wafer. This asymmetric pumping can result in non-uniform etch rate or deposition rate because of the changing concentration of reacting species as the gas flows towards the pump.

Asymmetric pumping can also result in non-uniform plasma density and electrical potential across the wafer since the pump port represents a location on the boundary of the plasma where there is a non-solid wall. Plasma may stream into this discontinuity in the wall and cause a disruption in the potential or density profile that is characteristic of the rest of the chamber's perimeter. FIG. 1 shows a typical etch rate map from an asymmetrically pumped chamber. It suggests that the presence of the pump port causes a non-uniform etch pattern that is aligned with the pump port. The arrows in the figure show the approximate direction of the gas flow as it exits the chamber through the pump port on the right.

One way to solve the asymmetric pumping effect is to design a chamber where the gas is pumped symmetrically around the entire perimeter of the wafer, often by placing the pump symmetrical to the workpiece. However, due to other design considerations this may not always be practical and this pump re-arrangement is not feasible in already existing chambers.

Accordingly, the present invention relates to a pump baffle and screen which can as a retrofit be placed in existing chambers or designed into new chambers to improve uniformity when asymmetric pump effect is a factor.

### SUMMARY OF THE INVENTION

The present invention provides a pump baffle and screen that partially blocks the pump port. The baffle causes a flow restriction that reduces the asymmetric pumping effect. The baffle also provides enough wall surface area across the pump port to reduce the electrical irregularities caused by the abrupt discontinuation of the solid wall.

### BRIEF DESCRIPTION OF THE DRAWINGS

The present invention will now be described by way of example with reference to the accompanying drawings wherein:

FIG. 1 is a diagram of a process chamber showing how asymmetric pumping affects etch rate uniformity of a silicon nitride wafer;

FIG. 2 is an exploded isometric view of a chamber assembly of the present invention showing the chamber housing, the chamber liner and the adapter plate;

FIG. 3 is an isometric view of the chamber housing;

FIG. 4 is an isometric view of the chamber liner;

FIG. 5a shows a top view of the chamber liner;

FIGS. 5b and 5c show two side views of the chamber liner, 5a a frontal view exposing the entire screen and 5b a side view showing a partial view of the screen and a partial view of the wafer insertion slot;

FIG. 6 is an isometric view of the adapter plate;

FIG. 7a shows a top view of the adapter plate;

FIG. 7b shows a bottom view of the adapter plate;

FIG. 7c show a side view of the adapter plate;

FIG. 8 shows a cross section view of an installed chamber liner and adapter plate;

FIGS. 9a and 9b shows two liner-screen designs;

FIG. 10 shows various graphs displaying the results of various liner screens in tests measuring uniformity performance.

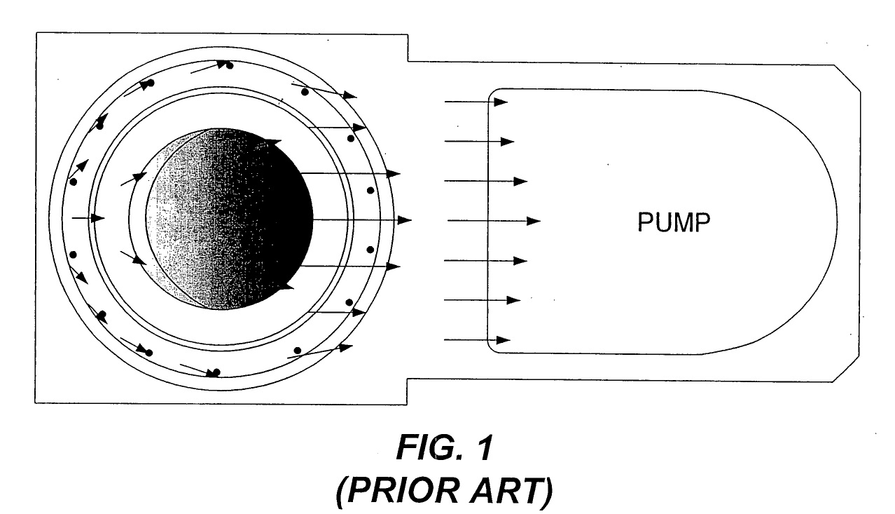

### DETAILED DESCRIPTION OF THE PREFERRED EMBODIMENTS

The present invention will now be described in detail with reference to a few preferred embodiments thereof as illustrated in the accompanying drawings. In the following descriptions, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

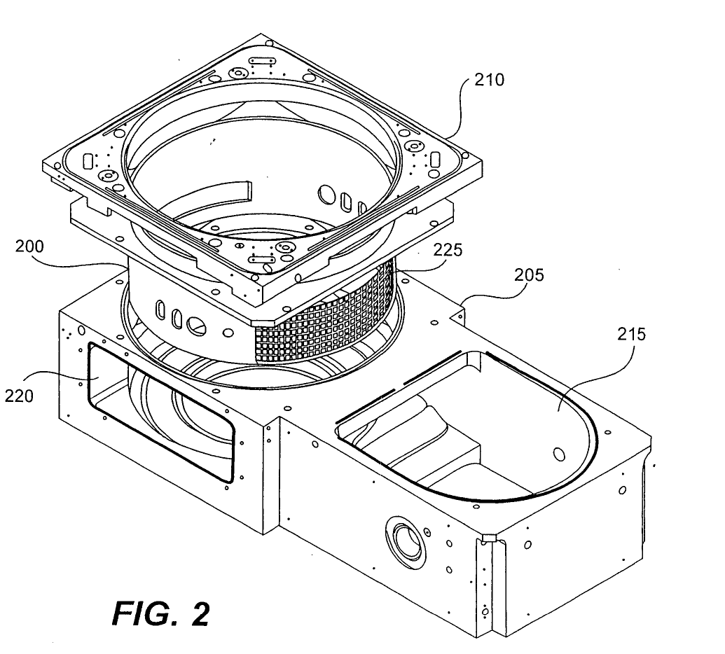

To facilitate discussion, FIG. 2 is an exploded view of the invention as it is designed to be incorporated into a chamber housing. The chamber liner 200, fits snugly into the chamber housing 205 and is secured to the housing by the adapter plate 210. The adjacent chamber pump port is shown as 215 and the view port window is shown as 220. The screen baffle portion of the chamber liner is shown as 225.

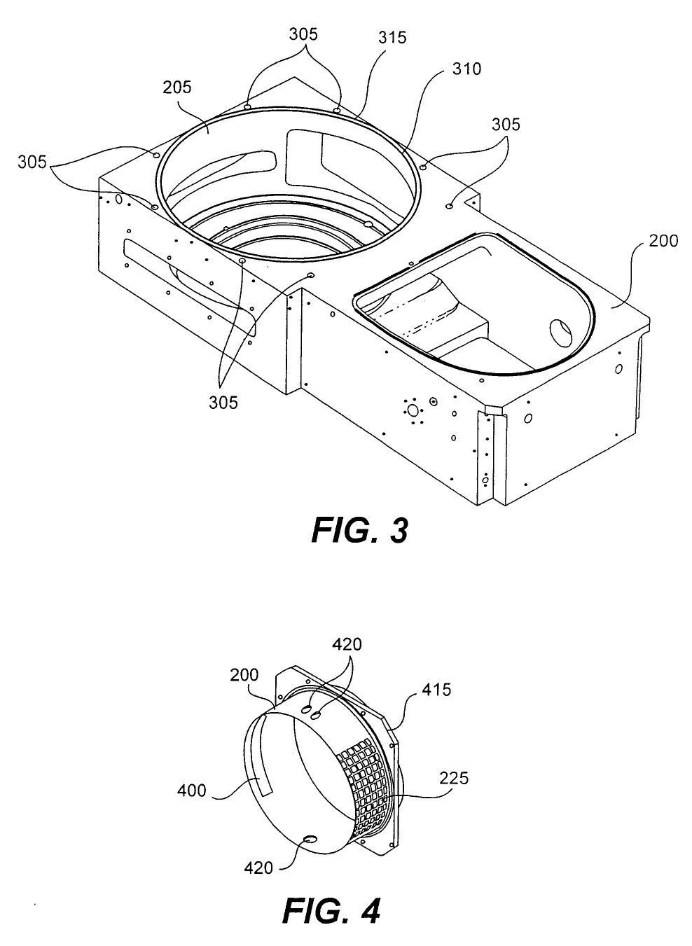

FIG. 3 shows an isometric view of the chamber housing 200 with chamber opening 205 and wafer opening 210. The chamber housing contains bolt holes 305 to allow the complete screen baffle apparatus to be securely and thermally attached to the chamber housing. The chamber housing also contains a dovetailed groove 310 to allow for the placement of a vacuum o-ring (comprised of any general elastomer type material, for example Viton) for sealing purposes and a polished ring portion 315 to allow for proper seating of a RF gasket.

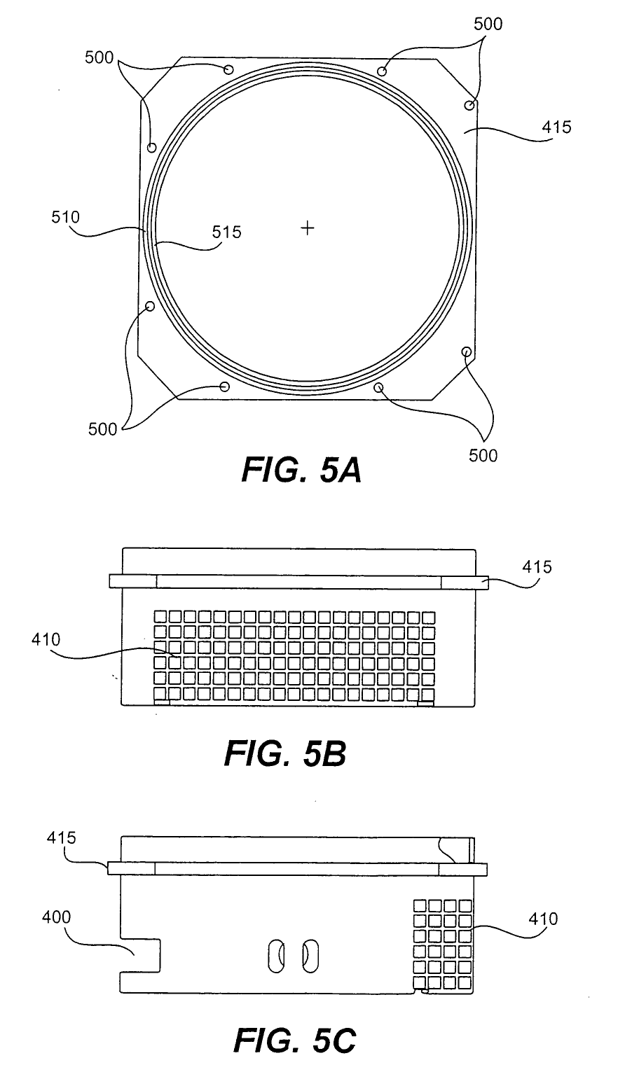

FIG. 4 shows an isometric view of the chamber liner 200. Shown is the wafer slot insertion opening 400 to accommodate wafer placement therethrough. The screen portion of the chamber liner is shown as 225. One of the difficulties with liner design is that liner temperature is not controlled. Since the liner sits in a vacuum, little heat is conducted to the walls of the chamber, and therefore, the liner heats up when exposed to plasma. This temperature change can be an important cause of process drift.

In the preferred embodiment, the liner design includes a broad horizontal tang or flange 415 that is clamped between two parts of the chamber (the main reaction chamber and the adapter plate). Any heat delivered from the plasma is conducted to the main chamber body through the tang or flange. Since the chamber temperature is controlled with cartridge heaters and an active temperature controller (not shown), the liner and the screen are held at the same temperature as the controller. Flange or tang portion 415 also allows the liner to be securely fastened to the chamber housing while also allowing thermal conductance such that the liner has thermal expansion and contraction reactions consistent with the chamber housing. Alternatively the liner could be actively heated or cooled with any variety of heating/cooling methods.

The chamber liner 200 can be typically manufactured from anodized aluminum and coated with a variety of resistant and process dependent favorable coatings including yttria, quartz and alumina. In a preferred embodiment, multiple chamber liners of varying coatings, all exhibiting process specific features can be interchanged in order to maximize chamber performance for a particular purpose. If necessary, access holes 420 can be machined through the chamber liner to allow for various endpointing access.

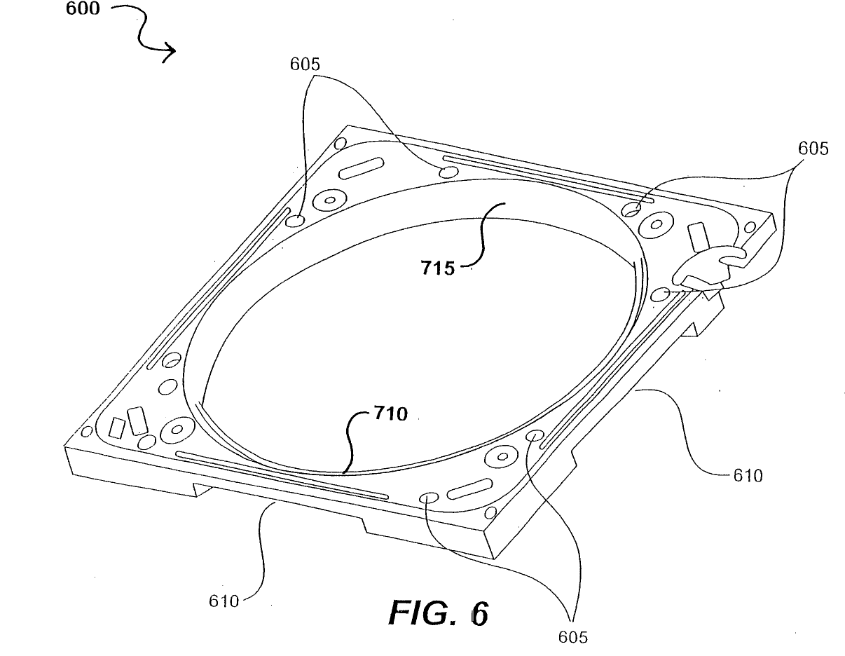

FIG. 5a shows a top views of the chamber liner with bolt holes 500 and flange (or tang) portion 415. Two polished ring portions of the chamber liner are shown as 510 and 515. The polished rings allow for proper seating of either the previously mentioned vacuum o-ring or RF gasket. The RF gasket is ideally placed outside of the o-ring gasket to avoid degradation from exposure to the plasma gasses. FIG. 5b shows a side view of the chamber liner with the screened baffle portion 410 fully exposed. The screened baffle portion of the liner should be the approximate dimension of the pump port opening. FIG. 5c shows a side view of the liner exposing a portion of the wafer insertion opening 400 and a portion of the screen baffle 410.

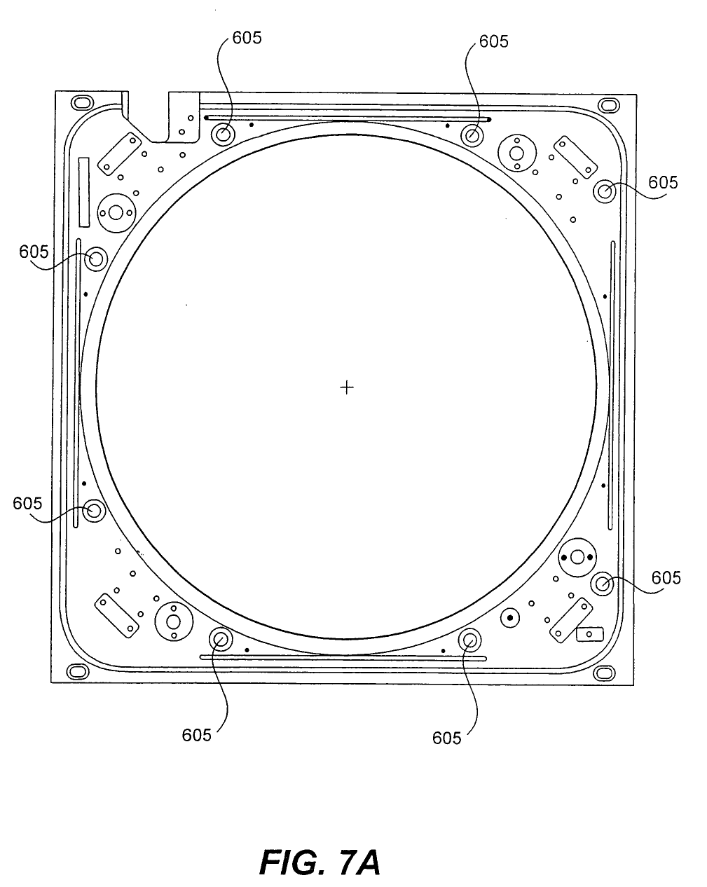

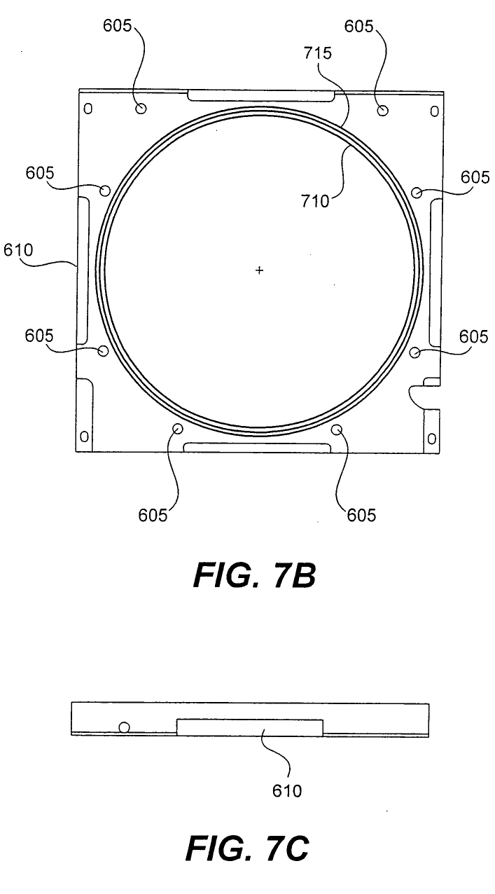

FIG. 6 shows an isometric view of the adapter plate 600. Nominally the adapter plate is also comprised of anodized aluminum and has bolt holes 605 to accommodate bolting of the entire assembly to the chamber housing and to facilitate thermal conductance. The adapter plate has slots or handles 610 machined therein for easy operator assembly, handling and manipulation. FIG. 7a is top view of the adapter plate showing bolt holes 605. FIG. 7b shows a bottom view with the inner dovetail groove 710 shown to accommodate the aforementioned vacuum o-ring as well as a polished ring portion 715 to facilitate seating of the RF gasket. FIG. 7c shows a side view of the adapter plate with the handle hold groove.

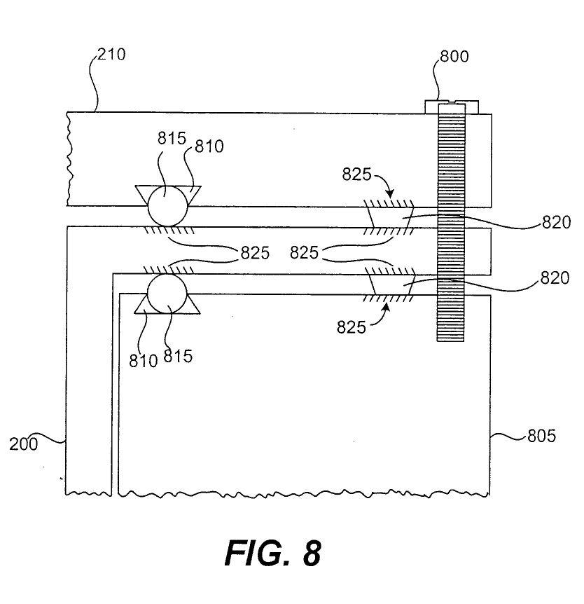

FIG. 8 shows a cross sectional view (not to scale) of an installed chamber liner 200. As shown, a bolt 800 securely fastens the adapter plate 200 to the chamber housing wall 805 through the chamber liner 200. Both the adapter plate 210 and the chamber liner wall 805 have dovetail joints 810 machined therethrough to facilitate the placement of the vacuum o-ring 815. RF gaskets are shown as 820 and polished metal portions 825 to allow for ring seating a present where either o-rings or RF gaskets come into contact with either the adapter plate, the chamber liner or the chamber housing.

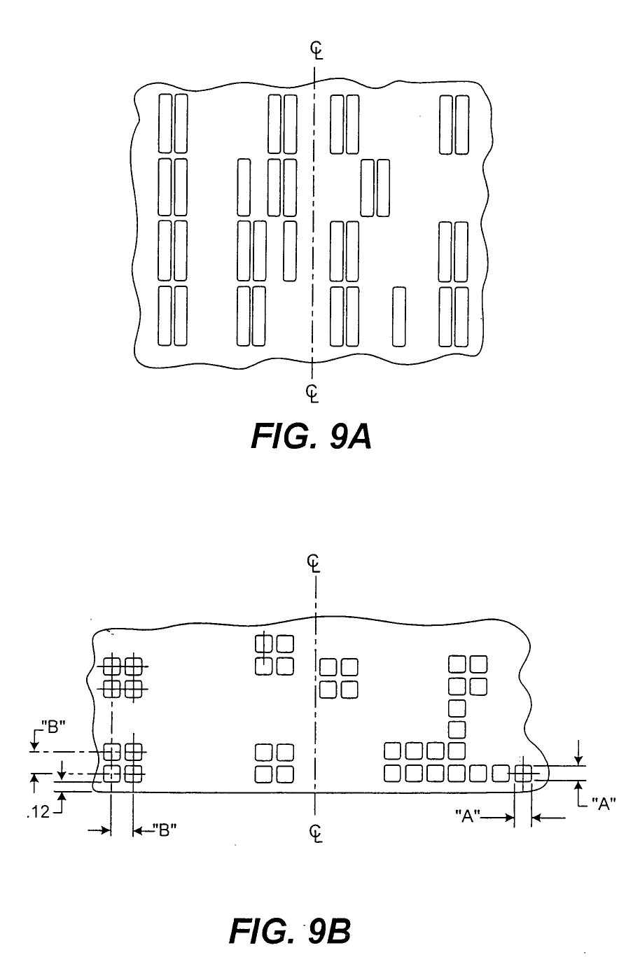

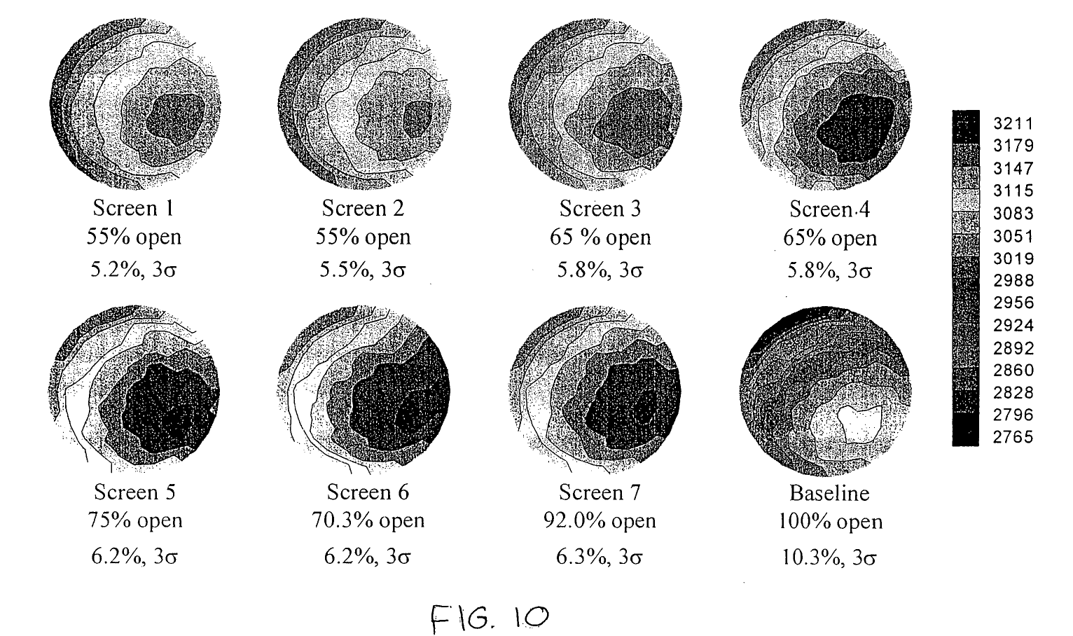

FIGS. 9a and 9b show two possible hole designs of the many possible variations in the design of the baffle or screen portion of the liner. Although there are various design considerations the one which has critical effect on uniformity results is simple “pass through” percentage; i.e., that percentage of screen area which does not contain screen material allowing gas or any other type of medium passage therethrough. As shown by the results given in FIG. 10, more than anything, the smaller the pass through percentage, (i.e. the more restrained the pump flow becomes), the more uniform the etching results become. Greater pass through percentage results in decreasing etch uniformity. Slots or rounds holes are also available as an alternative to the square holes depicted and may easier coatability.

Several versions of the liner were tested with different hole pitches (dimension B), and different hole sizes (dimension “A”). Also tested were long vertical slots as shown in FIG. 9b Different combinations of “A” and “B” were also tested which represented screen transparencies from 50% to 90%. A tabulation of these dimensions is shown in Table 1. As can be seen in FIG. 10, all combinations of “A” and “B” shown in Table 1 produced a significant improvement in etch uniformity. Sample test results for a typical nitride hardmask etch process are shown in FIG. 10. The improvement in etch uniformity for this process is nearly 50% for the screen with the smallest transparency.

TABLE 1
SCREEN DIMENSIONS

| | | Open area |
|---|---|---|
| | | percentage |
| “A” | “B” | (A/B)² |
| 0.188 | 0.249 | 57% |
| 0.250 | 0.334 | 56% |
| 0.250 | 0.307 | 66% |
| 0.375 | 0.453 | 68% |
| 0.375 | 0.431 | 76% |

1. A method of processing a substrate in a plasma processing chamber, comprising:
disposing said substrate within said plasma processing chamber;
striking a plasma within said plasma processing chamber to process said substrate; and
evacuating gaseous medium from said plasma processing chamber through an exhaust port that is at least partially covered by a screen, said screen reducing a flow rate of said gaseous medium relative to a flow rate that would have existed if said screen were absent, said screen being coupled to said plasma processing chamber via a flange.

2. The method of claim 1 wherein said screen is part of a cylindrical structure.

3. The method of claim 2 wherein said cylindrical structure includes a substrate insertion opening configured to facilitate substrate insertion into said plasma processing chamber, said disposing said substrate includes inserting said substrate through said substrate insertion opening.

4. The method of claim 2 wherein said screen is formed in a screen baffle region of said cylindrical structure, said screen baffle region having approximately the same area as a cross-section area of said exhaust port.

5. The method of claim 4 wherein said screen baffle region is disposed on only one side of said cylindrical structure.

6. The method of claim 1 wherein said screen is coated with one of the following materials: yttria, alumina, syria, quartz, and anodized aluminum.

7. The method of claim 1 wherein said flange is captured between said plasma processing chamber and an adapter.

8. The method of claim 1 wherein said screen is characterized by a pass through percentage, said pass through percentage being configured to improve process uniformity compared to a process uniformity that would have existed if said screen were absent.

9. A plasma processing system configured to process a substrate, comprising:
a plasma processing chamber configured to confine plasma during plasma processing of said substrate;
an exhaust port coupled to said plasma processing chamber, said exhaust port facilitating evacuation of gaseous medium from said plasma processing chamber; and
means for restricting a flow rate of said gaseous medium when said gaseous medium is evacuated from said plasma processing chamber, said means for restricting including a screen configured to reduce a pass through percentage of said gaseous medium when said gaseous medium is evacuated.

10. The plasma processing system of claim 9 wherein said screen is part of a cylindrical structure.

11. The plasma processing system of claim 10 wherein said cylindrical structure includes a substrate insertion opening configured to facilitate substrate insertion into said plasma processing chamber.

12. The plasma processing system of claim 10 wherein said screen is formed in a screen baffle region of said cylindrical structure, said screen baffle region having approximately the same area as a cross-section area of said exhaust port.

13. The plasma processing system of claim 12 wherein said screen baffle region is disposed on only one side of said cylindrical structure.

14. The plasma processing system of claim 10 wherein said cylindrical structure includes a flange.

15. The plasma processing system of claim 9 wherein said flange is captured between said plasma processing chamber and an adapter, thereby positioning said screen in front of an opening of said exhaust port.

16. The plasma processing system of claim 9 wherein said screen is coated with yttria.

17. The plasma processing system of claim 9 wherein said screen is coated with syria.

18. The plasma processing system of claim 9 wherein said screen is coated with quartz.

19. The plasma processing system of claim 9 wherein said screen is formed using anodized aluminum.

20. A method of retrofitting a plasma processing system having a plasma processing chamber, comprising:
providing a cylindrical structure having a screen portion and a flange;
positioning said cylindrical structure at least partially within said plasma processing chamber such that said screen portion at least partially overlaps an opening of an exhaust port of said plasma processing chamber, said screen portion reducing a flow rate of a gaseous medium through said exhaust port relative to a flow rate that would have existed if said screen portion were absent; and
securing said cylindrical structure by capturing said flange between said plasma processing chamber and an adapter.

21. The method of claim 20 wherein said cylindrical structure includes a substrate insertion opening configured to facilitate substrate insertion into said plasma processing chamber.

22. The method of claim 20 wherein said screen portion has approximately the same area as a cross-section area of said exhaust port.

23. The method of claim 20 wherein said screen is coated with one of the following materials: yttria, alumina, syria, quartz, and anodized aluminum.
